(19) United States
(12) Patent Application Publication
(10) Pub. No.: US 2026/0150212 A1
(43) Pub. Date: May 28, 2026

(54) METHOD FOR IMPROVING SCREEN DISTORTION IN DISPLAY AND ELECTRONIC DEVICE THEREFOR

(71) Applicant: SAMSUNG ELECTRONICS CO., LTD., Suwon-si (KR)

(72) Inventors: Changhoon JEONG, Suwon-si (KR); Junhui LEE, Suwon-si (KR); Jeongyeol LEE, Suwon-si (KR); Donghoo JANG, Suwon-si (KR); Jonggwan JUNG, Suwon-si (KR)

(73) Assignee: SAMSUNG ELECTRONICS CO., LTD., Suwon-si (KR)

(21) Appl. No.: 19/453,788

(22) Filed: Jan. 20, 2026

Related U.S. Application Data
(63) Continuation of application No. PCT/KR2024/010318, filed on Jul. 17, 2024.

(30) Foreign Application Priority Data
Jul. 20, 2023 (KR) 10-2023-0094701
Nov. 10, 2023 (KR) 10-2023-0155415

(51) Int. Cl. H05K 5/03; G04G 17/08

(52) U.S. Cl. CPC H05K 5/03; G04G 17/08

(57) ABSTRACT

An embodiment of the present disclosure provides a method for improving screen distortion (for example, moiré phenomenon) of a display, and an electronic device supporting the same. According to an embodiment, the electronic device may comprise a panel and a window formed on the panel. According to an embodiment, the window may comprise a front surface, a side surface, and a chamfer portion connecting the front surface and the side surface. According to an embodiment, the window may be diagonally processed such that a vertical straight section of the side surface of the window, which is perpendicular to the panel, extends from the chamfer portion and has a designated slope. According to an embodiment, the window may be processed such that the side surface of the window and/or the chamfer portion of the window have a designated shape on the basis of a refractive index of the window, and may be formed so as to prevent screen distortion on the basis of the designated shape. A window processing method according to an embodiment may comprise: a first setting process of setting the refractive index with regard to each material of a window; a second setting process of setting a designated processing scheme; a third setting process of setting a chamfer processing value corresponding to the refractive index in the designated processing scheme; and a processing process of processing a side surface and/or a chamfer portion of the window on the basis of the designated processing scheme and the chamfer processing value.

### CROSS-REFERENCE TO RELATED APPLICATIONS

This application is a bypass continuation application of International Application No. PCT/KR2024/010318, filed on Jan. 16, 2024, which claims priority to Korean Patent Application No. 10-2023-0094701, filed on Jul. 20, 2023, and Korean Patent Application No. 10-2023-0155415, filed on Nov. 10, 2023, in the Korean Intellectual Property Office, the disclosures of which are incorporated by reference herein in their entireties.

### BACKGROUND

### 1. Field

The disclosure relates to an electronic device and a method for improving screen distortion of a display (e.g., moiré phenomenon) and an electronic device supporting the same.

### 2. Description of Related Art

With the development of digital technology, various types of electronic device, such as a smart phone, a digital camera, and/or a wearable device, are widely used. Such an electronic device, for supporting and enhancing functions, continuously evolves in a hardware part and/or a software part of the electronic device.

The electronic device has become able to be equipped with various functions. The electronic device may include a touch screen-based display such that a user may easily access various functions, and may provide screens of various applications through the display.

With the recent development of technology, the electronic device departs from a uniform rectangular shape and is gradually transformed into various shapes. For example, the electronic device may include a wearable electronic device that can be worn on a part of a human body to increase convenience of use of a user.

The wearable electronic device may represent an electronic device that is miniaturized and reduced in weight and can be worn on a user's body. Since the wearable electronic device is highly portable, convenience of use may be enhanced. In addition, since the wearable electronic device has high proximity to the user's body, it may be utilized for various purposes.

The wearable electronic device (e.g., a wearable electronic device such as a watch type) may include a structure in which a window (or a plate) for protecting a panel is bonded to the panel, and a shape of the window may be determined according to a design of the wearable electronic device in most cases.

The wearable electronic device may have screen distortion (e.g., moiré phenomenon or light interference phenomenon) (hereinafter referred to as ‘moiré phenomenon’) depending on the shape of the window. For example, the moiré phenomenon may include a phenomenon in which incident light and reflected light are generated from the panel (e.g., a display) at the same wavelength, and the two rays of light of the same wavelength (e.g., the incident light and the reflected light) interfere with each other.

The information described above may be provided as the related art for the purpose of enhancing the understanding of the present disclosure. No assertion or determination is made with respect to the applicability of any of the above-mentioned as the prior art related to the present disclosure.

### SUMMARY

Provided is a method which may improve screen distortion (e.g., moiré phenomenon) in an electronic device including a display and an electronic device therefor.

Provided is a method which may reduce the moiré phenomenon (or screen distortion) by adjusting reflected light of a panel (e.g., the display) in an electronic device, and an electronic device therefor.

Technical problems to be solved by this document are not limited to the above-mentioned technical problems, and other technical problems, which are not described above, may be clearly understood from the following descriptions by those skilled in the art to which the present disclosure pertains.

According to an electronic device, an operation method thereof, and a recording medium according to one or more embodiments of the present disclosure, screen distortion that may occur during use of the electronic device may be eliminated, thereby improving visibility for use of the electronic device by a user. According to one or more embodiments, in an electronic device including a display, interference of incident light and reflected light caused by the display may be reduced, and through this, the screen distortion (e.g., moiré phenomenon) caused by the reflected light may be improved. According to one or more embodiments, the moiré phenomenon (or the screen distortion) may be reduced by adjusting reflected light of a panel (e.g., the display) in the electronic device. According to one or more embodiments, there is an effect of improving display quality by eliminating the moiré phenomenon. According to one or more embodiments, the moiré phenomenon may be eliminated or improved by changing a window structure according to a window material, regardless of a material of the window. According to one or more embodiments, the moiré phenomenon may be further improved even in a window of a designated material (e.g., sapphire glass).

According to one or more embodiments, regardless of a design of the electronic device, the moiré phenomenon may be removed by processing a shape of the window. According to one or more embodiments, the shape of the window may be processed with an inclination on the side surface in such a way as to have an optimum slope according to a window material, or the chamfer portion may be processed up to a total reflection angle region in which a moiré phenomenon occurs, according to the window material, thereby eliminating the moiré phenomenon.

In addition, various effects that can be directly or indirectly identified through the present document may be provided. The effects obtained by the disclosure are not limited to the aforementioned effects, and other effects, which are not mentioned above, will be clearly understood by those skilled in the art from the following description.

Additional aspects will be set forth in part in the description which follows and, in part, will be apparent from the description, or may be learned by practice of the presented embodiments.

According to an aspect of the disclosure, an electronic device including a panel; and a window on the panel. The window includes a front surface, a side surface, and a chamfer portion between the front surface and the side surface, the side surface includes a vertical straight section of the side surface, the vertical straight section is perpendicular to the panel and extends from the chamfer portion, and the side surface has a designated slope.

The window includes different refractive indexes at the side surface depending on a material of the window. The designated slope is based on a total reflection angle according to a refractive index of the window. The vertical straight section of the side surface includes a length calculated based on the total reflection angle.

The chamfer portion includes a designated width in a horizontal direction of the chamfer portion. The chamfer portion extends to the length of the vertical straight section of the side surface.

The chamfer portion includes a curved shape having a designated curvature, and a designated width in a horizontal direction of the chamfer portion. The chamfer portion extends to the length of the vertical straight section of the side surface.

The chamfer portion includes an equilateral portion having a designated size. The chamfer portion extends to the length of the vertical straight section.

The chamfer portion includes a designated curvature, and the vertical straight section of the side surface extends from a curved surface of the chamfer portion.

The chamfer portion includes an equilateral portion having a designated size according to a length calculated based on a total reflection angle, and the vertical straight section of the side surface extends from the equilateral portion of the chamfer portion to have the designated slope.

A structure housing the window.

The side surface includes a curved section extending from the vertical straight section.

The side surface includes a flange section extending from the curved section.

According to an aspect of the disclosure, a method of processing a window of an electronic device includes a first setting process for setting a refractive index for each material of the window; a second setting process for setting a designated processing scheme; a third setting process for setting a chamfer processing value corresponding to a refractive index in the designated processing scheme; and a processing process for processing a side surface and/or a chamfer portion of the window based on the designated processing scheme and the chamfer processing value.

The window is formed of a first material or a second material. The side surface of the window are formed to have different refractive indexes based on the first material or the second material. The first setting process is performed by using a total reflection angle according to the refractive index set for each material of the window.

The first setting process includes calculating a length of a vertical straight section of the side surface based on the total reflection angle. The second setting process includes performing by using a processing scheme corresponding to a structure change of the side surface of the window and/or a structure change of the chamfer portion of the window. The third setting process includes performing by using the chamfer processing value to process the side surface and/or the chamfer portion of the window. The chamfer processing value includes a slope of the side surface and/or a curvature of symmetry or asymmetry for a curved surface or a length of an equilateral portion, based on a shape of the chamfer portion formed between a front surface and the side surface. The processing process includes performing by using diagonal processing of the side surface of the window and/or chamfering processing of the chamfer portion of the window.

The designated processing scheme includes a scheme of diagonally processing a vertical straight section of the side surface of the window to have a designated slope, extending from the chamfer portion; and/or a chamfering processing scheme of increasing the area of the chamfer portion by having a designated width in a horizontal direction of the chamfer portion and extending by the length of the vertical straight section of the side surface.

According to an aspect of the disclosure, a non-transitory computer-readable recording medium storing one or more instructions. The one or more instructions, when executed by at least one processor, cause an electronic device to perform setting a refractive index for each material of a window; setting a designated processing scheme; setting a chamfer processing value corresponding to a refractive index in the designated processing scheme; and processing a side surface and/or a chamfer portion of the window based on the designated processing scheme and the chamfer processing value.

The window includes a first material and a second material. A refractive index of the first material is different than a refractive index of the second material.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an electronic device in a network environment according to various embodiments;

FIG. 2 is a perspective view of a front surface of an electronic device according to an embodiment of the present disclosure;

FIG. 3 is a perspective view of a rear surface of an electronic device according to an embodiment of the present disclosure;

FIG. 4 is an exploded perspective view of an electronic device according to an embodiment of the present disclosure;

FIG. 5 is a view illustrating an example of an electronic device according to an embodiment of the present disclosure;

FIG. 6 is a view illustrating an example of a window of an electronic device according to an embodiment of the present disclosure;

FIG. 7 is an exemplary view illustrating an example in which a moiré phenomenon occurs in a window of an electronic device according to an embodiment;

FIG. 8 is an exemplary view illustrating an example in which a moiré phenomenon occurs in a window of an electronic device according to an embodiment;

FIG. 9 is an exemplary view illustrating an example of improving a moiré phenomenon in an electronic device according to an embodiment of the present disclosure;

FIG. 10 is an exemplary diagram illustrating an example of processing a window of an electronic device according to an embodiment of the present disclosure;

FIG. 11A is a view illustrating an example of processing a window according to an embodiment of the present disclosure;

FIG. 11B is a view illustrating an example of processing a window according to an embodiment of the present disclosure;

FIG. 12 is a view illustrating an example of processing a window according to an embodiment of the present disclosure;

FIG. 13 is a view illustrating an example of processing a window according to an embodiment of the present disclosure;

FIG. 14 is a view illustrating an example in which a window is mounted in an electronic device according to an embodiment of the present disclosure;

FIG. 15 is a view illustrating an example in which a window is mounted in an electronic device according to an embodiment of the present disclosure; and

FIG. 16 is a flowchart illustrating an example of a method of processing a window of an electronic device according to an embodiment of the present disclosure.

### DETAILED DESCRIPTION

Hereinafter, embodiments of the present disclosure will be described in detail with reference to the accompanying drawings so that those with ordinary skill in the art to which the present disclosure pertains may easily carry out the embodiments. However, the present disclosure may be implemented in various different ways and is not limited to the embodiments described herein. In connection with the description of the drawings, the similar or same reference numerals may be used for the similar or same components. In addition, in the drawings and related descriptions, the description of well-known features and configurations may be omitted for clarity and conciseness.

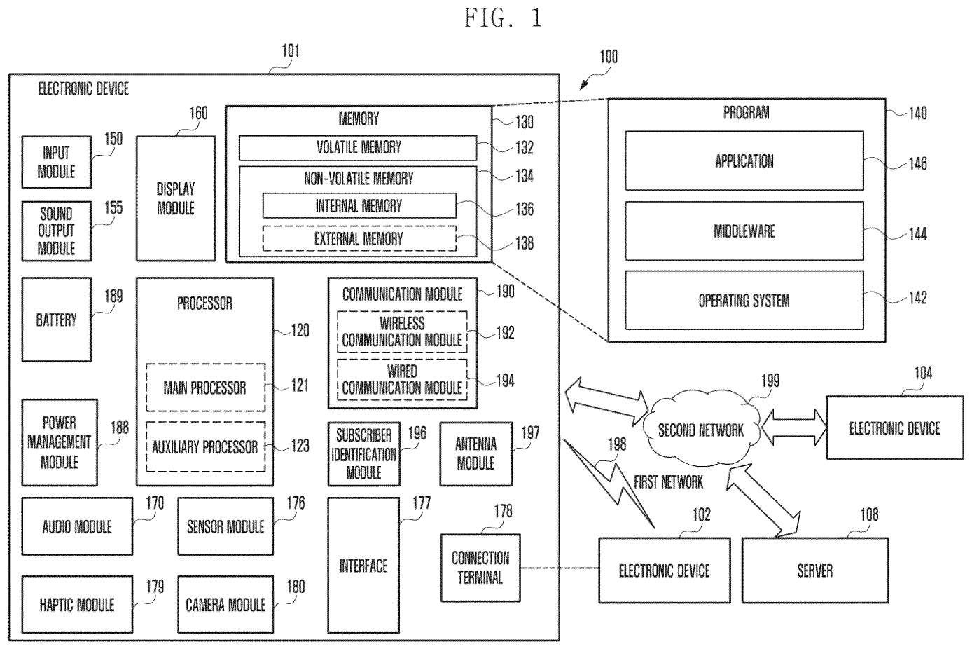

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wired) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wired) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology

Before describing various embodiments of the present disclosure, an electronic device (101) to which an embodiment of the present disclosure can be applied is described.

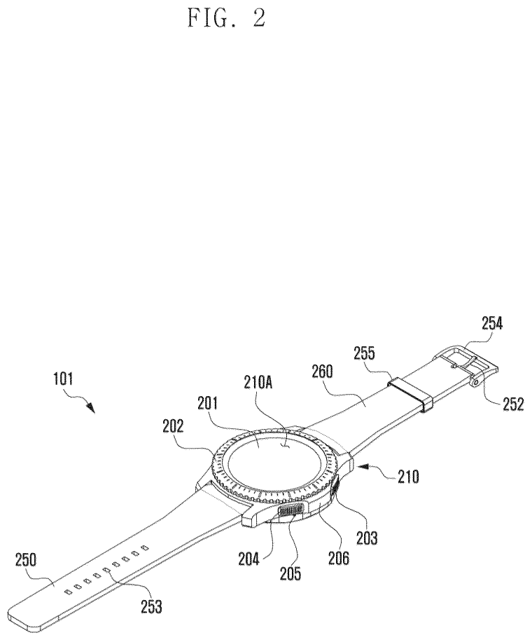

FIG. 2 is a perspective view of a front surface of an electronic device according to an embodiment of the present disclosure.

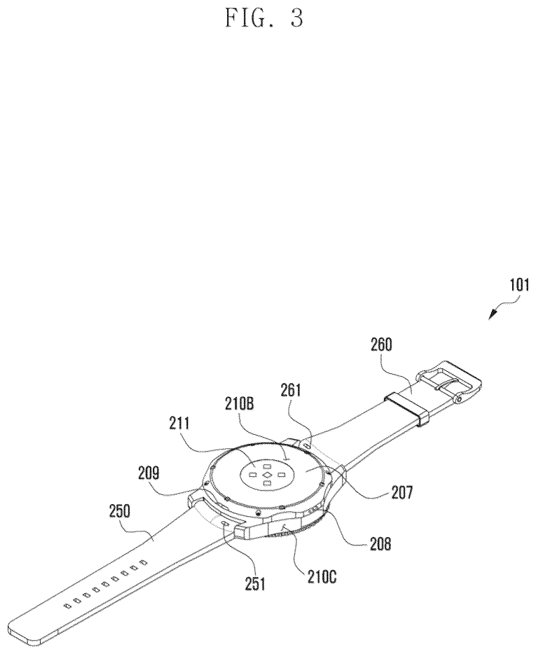

FIG. 3 is a perspective view of a rear surface of an electronic device according to an embodiment of the present disclosure.

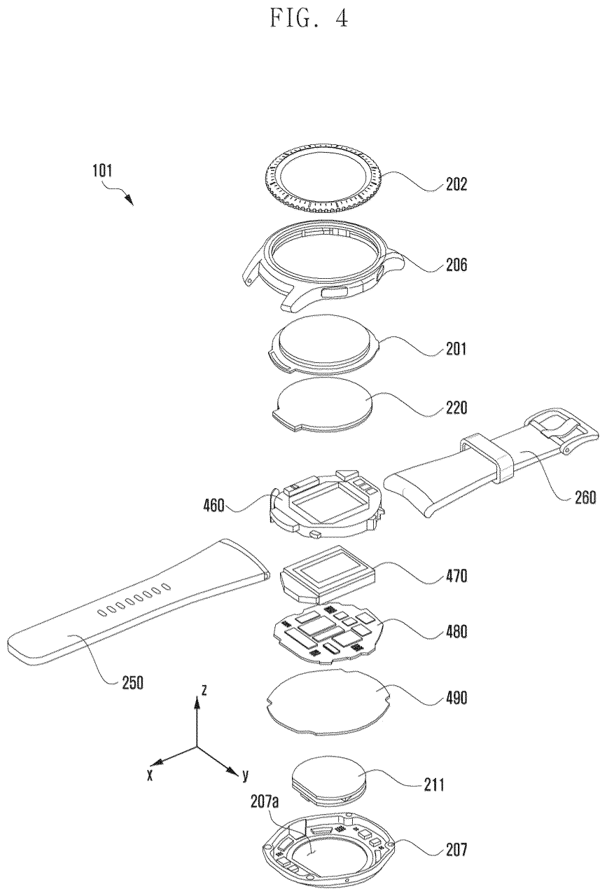

FIG. 4 is an exploded perspective view of an electronic device according to an embodiment of the present disclosure.

The electronic device 101 in FIGS. 2 to 4 may be at least partially similar to the electronic device 101 in FIG. 1, may include the electronic device 101 in FIG. 1, or may further include other embodiments of the electronic device 101. For example, the electronic device 101 may include a wearable electronic device that can be worn on a part of a human body.

With reference to FIGS. 2 and 3, the electronic device 101 according to an embodiment (e.g., a wearable electronic device, a wearable watch) may include a housing 210 including a first surface (also referred to as “front surface”) 210A, a second surface (also referred to as “rear surface”) 210B, and a side surface 210C surrounding a space between the first surface 210A and the second surface 210B, and a fastening member 250 and 260 connected to at least a portion of the housing 210 and configured to detachably fasten the electronic device 101 to a part of a user's body (e.g., a wrist, an ankle).

In an embodiment, the fastening member 250 and 260 may be, for example, a strap wound around a user's wrist to fix the electronic device 101. The fastening member 250 and 260 may be formed in various materials and forms. For example, the fastening member 250 and 260 may be formed of woven fabric, leather, rubber, synthetic resin, metal, ceramic, or a combination of at least two of the materials such that integrated and a plurality of unit links are movable with respect to each other.

In an embodiment, the housing 210 may also refer to a structure forming at least a portion of the first surface 210A, the second surface 210B, or the side surface 210C of the electronic device 101.

According to an embodiment, the first surface 210A may be formed by a front surface plate 201 in which at least a portion thereof is substantially transparent (e.g., a glass plate including various coating layers, or a polymer plate). The second surface 210B may be formed by a rear surface plate 207. The rear surface plate 207 may be formed, for example, of coated or colored glass, ceramic, polymer, metal (e.g., aluminum (Al), stainless steel (STS), or magnesium), or a combination of at least two of the materials (or substances). The side surface 210C may be coupled to the front surface plate 201 and the rear surface plate 207, and may be formed by a side surface bezel structure (or “side surface member”) 206 including metal and/or polymer. In an embodiment, the rear surface plate 207 and the side surface bezel structure 206 may be integrally formed and may include the same material (e.g., a metallic material such as aluminum).

According to an embodiment, the electronic device 101 may include at least one of a display (e.g., the display module 160 in FIG. 1 and/or the display 220 in FIG. 4), an audio module 205 and 208 (e.g., the audio module 170 in FIG. 1), a sensor module 211 (e.g., the sensor module 176 in FIG. 1), key input devices 202, 203, and 204 (e.g., the input module 150 in FIG. 1), or a connector hole 209 (e.g., the connecting terminal 178 in FIG. 1). In an embodiment, the electronic device 101 may omit at least one of the components (e.g., the key input devices 202, 203, and 204, the connector hole 209, or the sensor module 211) or may additionally include another component. According to an embodiment, the components are not limited to the parts illustrated in FIGS. 2 to 4.

The display 220 may be visually exposed through a substantial portion of the front surface plate 201, for example. For example, a user may identify at least one content displayed on the display 220 through the front surface plate 201. The shape of the display 220 may correspond to the shape of the front surface plate 201 and may be one of circular, elliptical, rectangular, and/or polygonal forms. The display 220 may be at least partially coupled with or disposed adjacent to a touch detection circuit, a pressure sensor capable of measuring intensity of a touch (e.g., pressure), and/or a fingerprint sensor.

The audio module 205 and 208 may include a microphone hole 205 and a speaker hole 208. The microphone hole 205 may include a microphone disposed therein for acquiring external sound. In an embodiment, the microphone may include a plurality of microphones disposed to detect a direction of sound. The speaker hole 208 may be used as an external speaker and a receiver for calls. In an embodiment, the speaker hole 208 and the microphone hole 205 may be implemented as a single hole, or a speaker (e.g., a piezo speaker) may be included without the speaker hole 208.

The sensor module 211 may generate an electrical signal or data value corresponding to an internal operating state of the electronic device 101, or an external environmental condition. The sensor module 211 may include, for example, a biometric sensor module (e.g., a biometric sensor, an HRM (heart rate monitor) sensor, an oxygen saturation sensor, and/or a blood glucose sensor) disposed toward the second surface 210B of the housing 210. When the electronic device 101 is worn on a part of a human body (e.g., a wrist), the sensor module 211 may be disposed in a manner that at least partially contacts the human body. The electronic device 101 may further include at least one of sensor modules not illustrated, for example, a gesture sensor, a gyro sensor, a barometer sensor, a magnetic sensor, an acceleration sensor, a grip sensor, a color sensor (e.g., an RGB (red, green, blue) sensor), an IR (infrared) sensor, a temperature sensor, a humidity sensor, and/or an illuminance sensor (e.g., an ALS, ambient light sensor).

The key input devices 202, 203, and 204 may include a wheel key 202 disposed corresponding to the first surface 210A of the housing 210 and rotatable along at least one direction (e.g., clockwise, counterclockwise), and/or side key buttons 203 and 204 disposed on the side surface 210C of the housing 210. The wheel key 202 may be in a form corresponding to a form of the front surface plate 201. According to an embodiment, the electronic device 101 may not include some or all of the above-described key input devices 202, 203, and 204, and the key input devices 202, 203, and 204 that are not included may be implemented in a form of a soft key and/or a touch key on the display 220.

The connector hole 209 may accommodate a connector (e.g., a USB connector) for transmitting and/or receiving power and/or data with an external electronic device (e.g., the electronic devices 102 and 104 in FIG. 1). The electronic device 101 may further include a connector cover (not illustrated) that covers at least a portion of the connector hole 209 and blocks foreign substances from entering the connector hole 209.

The fastening member 250 and 260 may be detachably fastened to at least a partial region of the housing 210 using a locking member 251 and 261. The fastening member 250 and 260 may include at least one of a fixing member 252, a fixing member fastening hole 253, a band guide member 254, or a band fixing ring 255. According to an embodiment, the electronic device 101 may be kept at least partially fastened to a part of a human body (e.g., a wrist) using the fastening member 250 and 260.

The fixing member 252 may be at least partially coupled with the fixing member fastening hole 253 such that the housing 210 and the fastening member 250 and 260 are fixed to a part of a user's body (e.g., a wrist or an ankle). The band guide member 254 may be configured to limit a movement range of the fixing member 252 when the fixing member 252 is fastened to the fixing member fastening hole 253, thereby allowing the electronic device 101 to be secured to a part of the body while the fastening member 250 and 260 is in close contact with a part of a user's body. The band fixing ring 255 may limit a movement range of the fastening member 250 and 260 while the fixing member 252 and the fixing member fastening hole 253 are fastened.

With reference to FIG. 4, the electronic device 101 may include a side surface bezel structure 206, the wheel key 202, the front surface plate 201, the display 220, a fixing member 460 (e.g., a support member), a battery 470, a printed circuit board 480, a sealing member 490, and the fastening member 250 and 260. For example, the fixing member 460 may be disposed inside the electronic device 101 and may be at least partially coupled with the side surface bezel structure 206, or may be integrally formed with the side surface bezel structure 206. The fixing member 460 may be formed of a metallic material and/or a non-metallic material (e.g., a polymer). The fixing member 460 may be coupled with the display 220 on one surface and may be coupled with the printed circuit board 480 on the other surface. According to an embodiment, a battery 470 may be disposed between the fixing member 460 and the printed circuit board 480, and the fixing member 460 and the printed circuit board 480 may be electrically connected. The fixing member 460 and the printed circuit board 480 may be electrically connected using a conductive member (e.g., a screw, a metallic material).

According to the embodiment, a processor (e.g., the processor 120 in FIG. 1), a memory (e.g., the memory 130 in FIG. 1), and/or an interface (e.g., the interface 177 in FIG. 1) may be mounted on the printed circuit board 480. The processor 120 may include at least one of, for example, a central processing unit (CPU), an application processor (AP), a graphic processing unit (GPU), a sensor processor, or a communication processor (CP).

According to an embodiment, the processor 120 may perform processing functions of an application layer required by a user of the electronic device 101. According to an embodiment, the processor 120 may provide control and commands of functions for various components of the electronic device 101. According to an embodiment, the processor 120 may perform calculations (operations) or data processing related to control and/or communication of respective components of the electronic device 101. For example, the processor 120 may include at least some of the configurations and/or functions of the processor 120 in FIG. 1. According to an embodiment, the processor 120 may be operatively connected with the components of the electronic device 101. According to an embodiment, the processor 120 may load into the memory 130 commands or data received from other components of the electronic device 101, may process the commands or data stored in the memory 130, and may store resulting data in the memory 130.

According to an embodiment, the processor 120 may include at least one processor including processing circuitry and/or executable program elements. According to an embodiment, the processor 120 may control (or process) overall operations related to processing a window processing operation (or process) based on the processing circuitry and/or the executable program elements.

According to an embodiment, the processor 120 may be a system semiconductor responsible for calculations (operations) and multimedia driving functions of the electronic device 101. According to an embodiment, the processor 120 may be configured in a form of a system-on-chip (SoC), may integrate various semiconductor technologies into one, and may include a technology-intensive semiconductor chip that implements system blocks in one chip.

According to an embodiment, the processor 120 may include an application processor (AP). According to an embodiment, the processor 120 may include components such as a graphics processing unit (GPU), an image signal processor (ISP), a central processing unit (CPU), a neural processing unit (NPU), a digital signal processor (DSP), a modem, connectivity, and/or security. According to an embodiment, the processor 120 may operate individually and/or collectively.

According to an embodiment, operations performed by the processor 120 may be implemented by executing instructions stored in a recording medium (or a computer program product or a storage medium). For example, the recording medium may include a non-transitory computer-readable recording medium that records a program for executing various operations performed by the processor 120.

The embodiments disclosed herein may be implemented in a recording medium readable by a computer or similar device using software, hardware, or combinations thereof. According to hardware implementations, the operations described in an embodiment may be implemented using at least one of application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, and/or electrical units for performing other functions.

In an embodiment, there is provided a computer-readable recording medium (or a storage medium or a computer program product) in which a program for performing (or executing) various operations in the electronic device 101 is recorded.

The operations may include an operation of setting a refractive index for each material of the window 600 (e.g., a first setting process), an operation of setting a designated processing scheme (e.g., a second setting process), an operation of setting a chamfer processing value corresponding to a refractive index in the designated processing scheme (e.g., a third setting process), and an operation of processing the side surface and/or the chamfer portion 610 of the window 600 based on the designated processing scheme and the chamfer processing value (e.g., a processing process).

The memory 130 may include, for example, a volatile memory or a non-volatile memory. The interface (or connector) may electrically or physically connect the electronic device 101 and an external electronic device, and may include at least one of an HDMI (high definition multimedia interface), a USB (universal serial bus) interface, an SD (secure digital) card/MMC (multi-media card) interface, and/or an audio interface.

According to an embodiment, the memory 130 may store instructions that, when executed individually and/or collectively by at least one processor (e.g., the processor 120 in FIG. 1), cause the electronic device 101 to perform operations.

According to an embodiment, the instructions, when executed by at least one processor, may cause the electronic device 101 to set a refractive index for each material of the window 600. According to an embodiment, the instructions, when executed by at least one processor, may cause the electronic device 101 to set a designated processing scheme. According to an embodiment, the instructions, when executed by at least one processor, may cause the electronic device 101 to set a chamfer processing value corresponding to a refractive index in the designated processing scheme. According to an embodiment, the instructions, when executed by at least one processor, may cause the electronic device 101 to process the side surface and/or the chamfer portion 610 of the window 600 based on the designated processing scheme and the chamfer processing value.

The battery 470 (e.g., the battery 189 in FIG. 1) may be a device for supplying power to at least one component of the electronic device 101, and may include at least one of a non-rechargeable primary battery, a rechargeable secondary battery, or a fuel cell, for example. At least a portion of the battery 470 may be disposed on substantially the same plane as the printed circuit board 480, for example. The battery 470 may be integrally disposed inside the electronic device 101, and may also be disposed to be detachable from the electronic device 101.

The printed circuit board 480 may include (e.g., mount) at least one antenna (e.g., an antenna module, a chip antenna). For example, the at least one antenna may include at least one of an NFC (near field communication) antenna, a wireless charging antenna, and/or an MST (magnetic secure transmission) antenna. The at least one antenna may perform near-field communication with an external device, may wirelessly transmit and receive power necessary for charging, and may transmit a magnetic-based signal including a near-field communication signal or payment data. According to an embodiment, an antenna structure may be formed by at least a part of, or a combination of, the side surface bezel structure 206, the front surface plate 201, and/or the fixing member 460. According to an embodiment, the fixing member 460 and the printed circuit board 480 may be electrically connected, and an electric field (E-field) may be formed based on the fixing member 460 and the printed circuit board 480. The electronic device 101 may transmit and receive communication signals based on the formed electric field (E-field), and may utilize at least a portion of the fixing member 460 as an antenna.

The sealing member 490 may be located between the side surface bezel structure 206 and the rear surface plate 207. The sealing member 490 may be configured to block moisture and foreign substances introduced from the outside into a space surrounded by the side surface bezel structure 206 and the rear surface plate 207.

The sensor module 211 (e.g., a biometric sensor) may be disposed adjacent to the rear surface plate 207. For example, when the electronic device 101 is worn on a part of a wearer's body (e.g., a wrist), the rear surface plate 207 may be disposed while at least partially contacting a part of the body. The sensor module 211 may be disposed in a manner as to be oriented toward a part of the body (e.g., a wrist, skin). The sensor module 211 may transmit signals of various wavelength bands toward a part of the wearer's body. The electronic device 101 may acquire various biometric information (e.g., information related to heartbeats, blood glucose-related information, and/or oxygen saturation) based on the signals of the wavelength bands reflected, scattered, and/or absorbed from a part of the wearer's body. According to an embodiment, the rear surface plate 207 may be implemented in such a manner that a rear surface window 207a is at least partially coupled so that the above-described signals are transmitted there through.

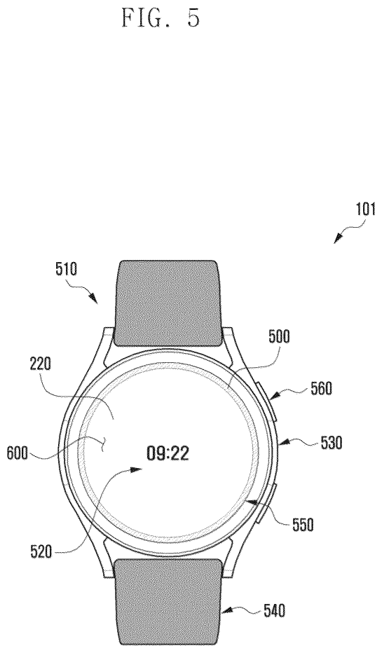

FIG. 5 is a view illustrating an example of an electronic device according to an embodiment of the present disclosure.

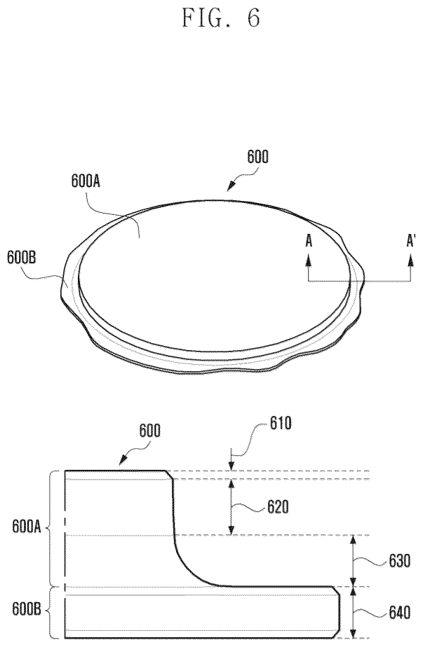

FIG. 6 is a view illustrating an example of a window of an electronic device according to an embodiment of the present disclosure.

In an embodiment, the electronic device 101 in FIG. 5 may be at least partially similar to, or may include, the electronic device 101 in FIGS. 1 to 4. For example, the electronic device 101 may include a wearable electronic device (e.g., a wearable watch) that can be worn on a part of a human body. According to an embodiment, the electronic device 101 may be implemented by including at least some of the components in FIGS. 1 to 4, or by additionally including other components.

In an embodiment, the electronic device 101 may include a display 220 (e.g., the display module 160 in FIG. 1 or the display 220 in FIGS. 2 to 4) on a front surface 510 (e.g., the first surface 210A in FIGS. 2 to 4). The electronic device 101 may be a wearable electronic device (e.g., a wearable watch) that can be worn by a user in the form of a watch. The electronic device 101 may display an interface 520 related to a watch on at least a portion of the display 220.

In an embodiment, the electronic device 101 may include a case 530 (e.g., the housing 210 in FIGS. 2 to 4) and a band 540 (or strap) (e.g., the fastening member 250 and 260 in FIGS. 2 to 4).

In an embodiment, the case 530 may externally include a bezel 550 (e.g., the side surface bezel structure 206 in FIGS. 2 to 4), a crown 560 (e.g., the input module 150 in FIG. 1 or the side key buttons 203 and 204 in FIGS. 2 to 4), and the display 220. The case 530 may internally or externally include the processor 120, the memory 130, the input module 150, the sound output module 155, the display module 160, the audio module 170, the sensor module 176, the interface 177, the connecting terminal 178, the haptic module 179, the camera module 180, the power management module 188, the battery 189, the communication module 190, the subscriber identification module 196, and/or the antenna module 197 which are shown in FIG. 1.

In an embodiment, on the front surface 510 of the case 530, the display 220 may be disposed, and on the rear surface (e.g., the second surface 210B in FIGS. 2 to 4), at least a portion (e.g., a biometric sensor module) of a sensor circuit (e.g., the sensor module 211 in FIGS. 2 to 4) may be exposed to the outside.

In an embodiment, when the electronic device 101 is worn by a user through the band 540, at least a portion of the rear surface of the case 530 may contact the user.

In an embodiment, the bezel 550 may be concentric with the circular display 220, and may be in a ring shape. An inner radius of the bezel 550 may match a radius of the display 220. The bezel 550 may be disposed at an edge portion of the case 530 to protect the display 220 from an external impact.

In an embodiment, the bezel 550 may be rotated in at least one direction of clockwise or counterclockwise. The bezel 550 may perform a role of an input device of the electronic device 101. When the bezel 550 rotates, the electronic device 101 may determine a speed and/or direction of the rotation of the bezel 550 as a user input, and may control a function of the electronic device 101 according to the user input.

In an embodiment, the crown 560 may be disposed to protrude beyond at least a partial region of the case 530. The crown 560 may have a shape of one of a cylindrical column, an elliptical column, a rectangular column, or a polygonal column. The crown 560 may be connected to the case 530 around a rotation axis to be rotatable. The crown 560 may be connected to the case 530 by a stem providing the rotation axis to be rotatable. Without limitation, the crown 560 may be in a form of a key button (e.g., the side key buttons 203 and 204 in FIGS. 2 to 4).

In an embodiment, the crown 560 may perform a role of an input device of the electronic device 101. When the crown 560 rotates, the electronic device 101 may determine a speed and direction of the rotation of the crown 560 as a user input, and may control a function of the electronic device 101 according to the user input. In an embodiment, if the crown 560 is in a key button form, when the crown 560 is pressed, the electronic device 101 may determine, based on the number of times the crown 560 is pressed or the duration of the pressing, as a user input, and may control a function of the electronic device 101 according to the user input.

In an embodiment, the band 540 may allow the electronic device 101 to be seated on a wrist of a user. The band 540 may be formed of various materials such as metal, rubber, and leather. The band 540 may be connected to one end of the case 530, and the band 540 connected to the case 530 may be replaceable.

Although not illustrated, according to an embodiment, the electronic device 101 may include, inside the electronic device 101, at least one of an input device (e.g., a microphone), a sound output device, a sensor module, a camera device, a key input device, a communication circuit, and/or a connector port.

According to an embodiment, the electronic device 101 may include a window 600 (e.g., the front surface plate 201 in FIGS. 2 to 4). An example of the shape of the window 600 according to an embodiment is illustrated in FIG. 6.

With reference to FIGS. 5 and 6, the window 600 (e.g., the front surface plate 201 in FIGS. 2 to 4) may include a glass plate including various coating layers, or a polymer plate. According to an embodiment, the window 600 may be coupled with the case 530. According to an embodiment, the display 220 may be visually exposed through a substantial portion of the window 600. For example, a user may identify at least one content (e.g., the interface 520) displayed on the display 220 through the window 600. The shape of the display 220 may correspond to the shape of the window 600.

In an embodiment, the window 600 may include an upper end portion 600A and a lower end portion 600B. In an embodiment, the lower end portion 600B may have a larger area than the upper end portion 600A. For example, a diameter of the lower end portion 600B may be larger than a diameter of the upper end portion 600A. According to an embodiment, with reference to a cross-section along an A-A′ direction, the upper end portion 600A may include a chamfer portion (or C-cut section) 610 (e.g., a diagonally cut portion of an edge of the upper end portion 600A of the window 600)), a straight section 620, and a curved section (or R section) 630. According to an embodiment, with reference to a cross-section along an A-A′ direction, the lower end portion 600B may include a flange section 640. In an embodiment, the lower end portion 600B may be a flange for reinforcement or connection of the upper end portion 600A of the window 600.

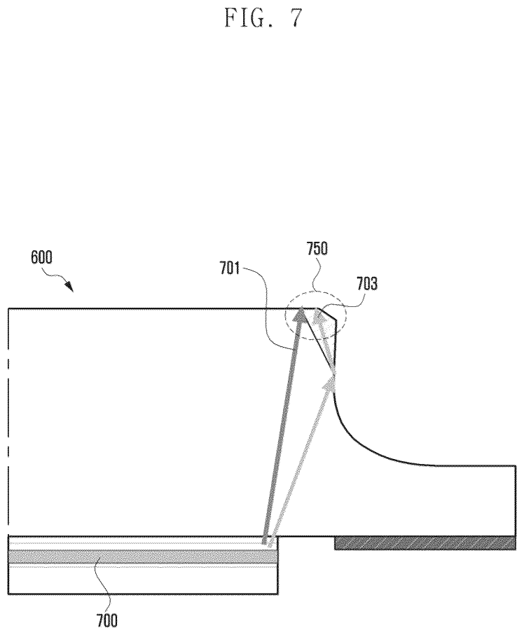

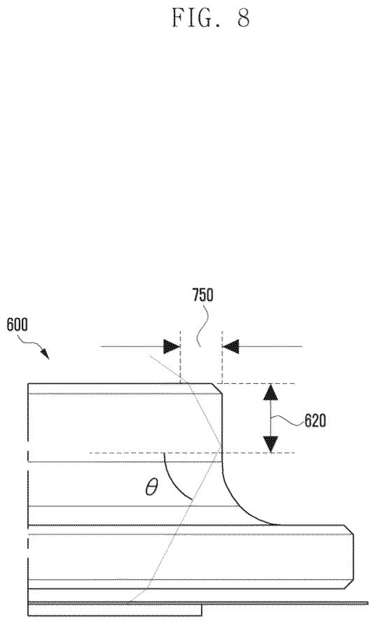

According to an embodiment, the electronic device 101 may have a screen distortion (e.g., a moiré phenomenon (e.g., a screen distortion phenomenon caused by light interference)) depending on the shape of the window 600. For example, in the window 600, the moiré phenomenon may occur at a front surface of the window 600. For example, as in a hatched region illustrated in FIG. 5, the moiré phenomenon may occur at an outer edge of the front surface of the window 600 (e.g., an edge region 500 of the window 600). According to an embodiment, occurrence of the moiré phenomenon will be described with reference to FIGS. 7 and 8.

FIG. 7 is an exemplary view illustrating an example in which a moiré phenomenon occurs in a window of an electronic device according to an embodiment.

FIG. 8 is an exemplary view illustrating an example in which a moiré phenomenon occurs in a window of an electronic device according to an embodiment.

With reference to FIGS. 7 and 8, the moiré phenomenon may include a phenomenon in which incident light 701 and reflected light 703 are generated from a panel 700 (e.g., the display 220 in FIGS. 2 to 5) and the two rays of light of the same wavelength (e.g., the incident light 701 and the reflected light 703) interfere with each other at the front surface of the window 600, as illustrated by the moiré occurrence region 750. In an embodiment, the moiré may include a water ripple moiré or a scan line moiré. For example, when the moiré phenomenon occurs, a screen distortion such as a moiré pattern caused by a linear lattice or a moiré pattern caused by a circular lattice may appear at an outer edge of the window 600, as in the edge region 500 in FIG. 5.

In an embodiment, the incident light 701 in FIG. 7 may represent light that reaches the front surface of the window 600 without reflection (or refraction), as indicated by the arrow direction of the element referenced by 701. For example, the incident light 701 may represent light that is output from the panel 700 and directly enters the front surface of the window 600. In an embodiment, the reflected light 703 in FIG. 7 may represent light that is reflected (or refracted) off a side surface (e.g., the straight section 620 in FIG. 6) (e.g., a total reflection region of the side surface) of the window 600 and reaches the front surface of the window 600, as indicated by the arrow direction of the element referenced by 703. For example, the reflected light 703 may include light that is emitted from the panel 700, is reflected from the side surface of the window 600, and reaches the front surface of the window 600 (e.g., the front surface of the window 600).

According to an embodiment, the moiré phenomenon in the window 600 may appear differently depending on the material forming the window 600. For example, the window 600 may be formed of various materials, such as in a window of a first material (e.g., gorilla glass) or a window of a second material (e.g., sapphire glass). According to an embodiment, the window 600 may have a different refractive index (or index of refraction) depending on the material. In an embodiment, the refractive index may be defined, for example, as a value obtained by dividing the speed of a wave in a first medium (or an internal medium) (e.g., a transparent glass such as the first material or second material of the window 600) by the speed of a wave passing through a second medium (or an external medium) (e.g., air outside the window 600), and may be referred to as the refractive index of the second medium with respect to the first medium.

For example, the refractive index may represent a degree to which a wave passing through a boundary surface between different media is refracted. In an embodiment, the boundary surface may represent a surface on which a property of a material significantly changes, causing a substantial change in the propagation direction or speed of a wave such as light.

According to an embodiment, in a case of a window of the second material (e.g., sapphire glass) recently applied to the electronic device 101, the refractive index may be greater compared to a window of the first material (e.g., gorilla glass). Therefore, in a case of the window 600, there may be a difference in refractive index depending on the material, and in a window of a material having a large refractive index (e.g., a window of a second material), total reflection may occur frequently at a side surface of the window 600 (e.g., the straight section 620 in FIG. 6 or FIG. 8) (e.g., a total reflection angle (θ) region), and thus the amount of interference of light may increase. In FIG. 8, “θ” may represent an angle (e.g., a total reflection angle (θ)) at which the reflected light 703 totally reflects at a side surface of the window 600 (e.g., the straight section 620 in FIG. 6 or FIG. 8). For example, in a window of a material having a large refractive index, the moiré phenomenon may occur more frequently at an outer edge, and screen distortion of the display 220 may be intensified.

According to an embodiment, in the electronic device 101, the window 600 may be bonded onto the panel 700 (e.g., the display 220). According to an embodiment, the window 600 may include a front surface, a side surface, and a chamfer portion 610 connecting the front surface and the side surface. According to an embodiment, total reflection (total reflection or total internal reflection) may occur at a side surface of the window 600, which is a section perpendicular to the panel 700 (e.g., the straight section 620 in FIG. 6 or FIG. 8),, and the moiré phenomenon may occur at a front surface of the window 600 (e.g., an edge region of the upper end portion 600A of the window 600 (e.g., the moiré occurrence region 750 in FIG. 7 or FIG. 8)) where the reflected light reflected from the section (e.g., the side surface) perpendicular to the panel 700 interferes with the incident light.

In an embodiment of the present disclosure, the moiré phenomenon may be improved by adjusting the reflected light of the panel 700. In an embodiment of the present disclosure, there is provided a design of the side surface of the window 600 (e.g., the straight section 620 in FIG. 6 or FIG. 8) that may suppress the reflected light causing the moiré phenomenon, and/or a design of the shape of the window chamfer portion (e.g., the chamfer portion 610 in FIG. 6) based on an optical simulation result. For example, in the present disclosure, the reflected light causing the moiré phenomenon may be suppressed through a design change (or processing) of at least one portion of the window 600.

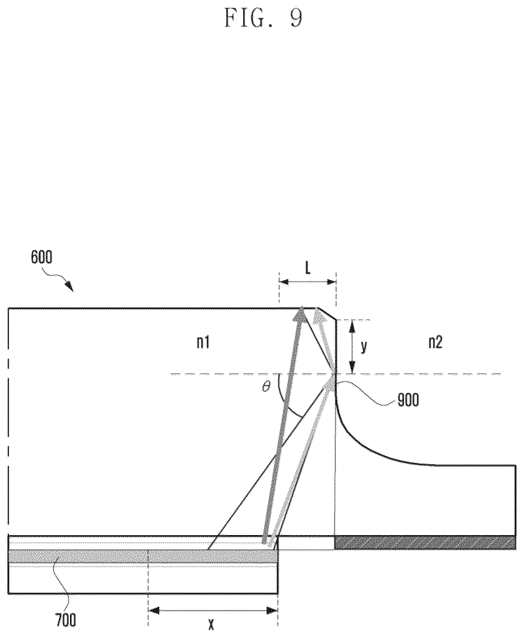

FIG. 9 is an exemplary view illustrating an example of improving a moiré phenomenon in an electronic device according to an embodiment of the present disclosure.

With reference to FIG. 9, “θ” in FIG. 9 may represent an angle (e.g., a total reflection angle) at which the reflected light totally reflects at a side surface (or side surface boundary surface) 900 of the window 600 (e.g., the straight section 620 in FIG. 6 or FIG. 8). According to an embodiment, a critical angle (θc) corresponding to the total reflection angle (θ) (e.g., a total reflection critical angle) may be calculated as in Equation 1 below. In an embodiment, the critical angle may represent a minimum incident angle at which total reflection occurs.

$${θ}_{c} = {sin}^{- 1} ( \frac{n 1}{n 2} ) \qquad [ Equation 1 ]$$

In Equation 1, n1 and n2 may respectively represent a refractive index of each of two media (e.g., an internal medium and an external medium) on both sides of the side surface 900 of the window 600. For example, n1 may represent the refractive index of an internal medium of the window 600 (e.g., a transparent glass such as the first material or the second material), and n2 may represent the refractive index of an external medium of the window 600 (e.g., air). For example, the refractive index of glass may be about 1.5 (e.g., n1=about 1.5), and the refractive index of air may be about 1 (e.g., n2=about 1).

In general, the side surface 900 of the window 600 bonded on the panel 700, which is a section perpendicular to the panel 700 (e.g., the straight section 620 perpendicular to the panel 700 in FIG. 6 or FIG. 8) may play a decisive role in the moiré phenomenon, and depending on an actual position and size of the panel 700, a length (x) affecting the moiré phenomenon (e.g., a length affecting total reflection out of the entire length of the panel 700 (e.g., a length formed inward from the outside of the panel 700) may vary. For example, a region (e.g., a length) of the panel 700 affecting the side surface total reflection of the window 600 may be referred to as “x”, and a length (e.g., a height) of the side surface 900 affecting the moiré phenomenon may be assumed to be “y”. According to an embodiment, the region “x” of the panel 700 affecting the side surface total reflection may be defined as in Equation 2 below, and by using Equation 2, a straight section (e.g., a length “y”) of the side surface 900 actually affecting the moiré phenomenon (e.g., a total reflection angle region) may be calculated.

$$x = \frac{y}{tan θ} \qquad [ Equation 2 ]$$

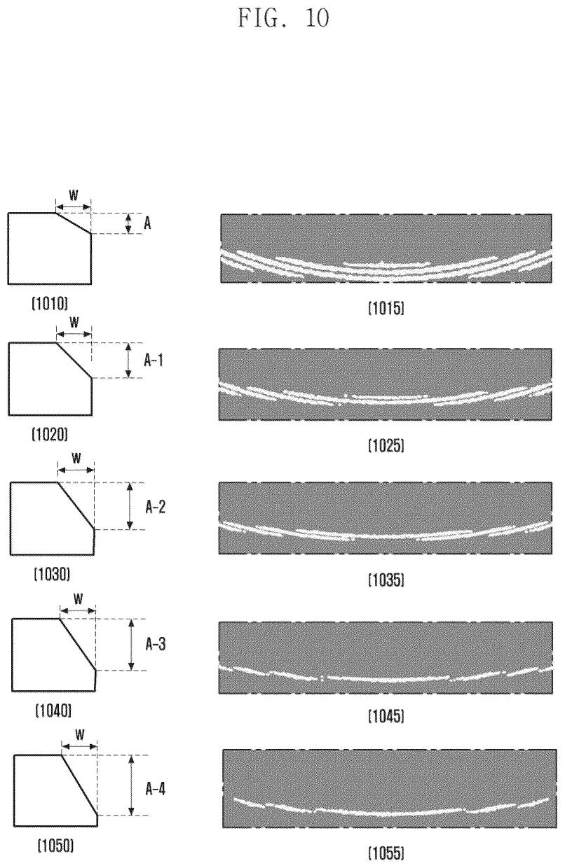

According to an embodiment, a total reflection angle (0) may vary according to a refractive index of a material of the window 600, and by using this, a length of a straight section (e.g., a “y” length) affecting a moiré phenomenon may be calculated. According to an embodiment, in order to eliminate the moiré phenomenon, within a region (L) (e.g., the moiré occurrence region 750 in FIG. 7 or FIG. 8) in which the moiré phenomenon occurs at a front surface of the window 600, the side surface 900 of the window 600 may be processed (e.g., chamfering processing) based on the “y” length (e.g., a total reflection angle region) out of the entire straight section (e.g., the straight section 620 in FIG. 6 or FIG. 8) of the side surface 900, thereby improving (e.g., eliminating) the moiré phenomenon. An example thereof is illustrated in FIG. 10.

FIG. 10 is an exemplary diagram illustrating an example of processing a window of an electronic device according to an embodiment of the present disclosure.

According to an embodiment, FIG. 10 may illustrate an example of a result of a test of improving the moiré phenomenon according to a chamfering processing of a chamfer portion (e.g., the chamfer portion 610 in FIG. 6) of the window 600.

With reference to FIG. 10, elements 1010, 1020, 1030, 1040, and 1050 may represent examples of one portion corresponding to the chamfer portion 610 of the window 600. Elements 1015, 1025, 1035, 1045, and 1055 may represent examples of test results according to chamfering processing of the window 600 (e.g., examples of the moiré phenomenon appearing at an edge region 500 of the window 600 in FIG. 5). For example, the element 1010 may represent an example of the window 600 having a chamfer portion 610 according to a basic design (or existing design) (e.g., a chamfer portion 610 in a state of not being chamfered), and the element 1015 may represent an example of the moiré phenomenon shown at an outer edge (e.g., the edge region 500 of the window 600 in FIG. 5) in the window 600 having a chamfer portion according to the basic design.

According to an embodiment, during chamfering processing of the chamfer portion of the window 600, a width (w) (or horizontal length or width) of the chamfer portion may be fixed, and a depth (A) (or vertical length or height) of the chamfer portion may be changed to change a shape of the chamfer portion. For example, a length of a straight section (e.g., a “y” length) (e.g., total reflection angle region) affecting the moiré phenomenon at a straight section (e.g., the straight section 620 perpendicular to the panel 700 in FIG. 6 or FIG. 8) of the upper end portion 600A of the window 600 may be calculated, and the depth (A) of the chamfer portion may be processed to match the calculated “y” length, thereby processing a shape of the chamfer portion. For example, depending on a difference of the depth (A) of the chamfer portion according to the “y” length, a length (or size) of an equilateral portion (e.g., a diagonal surface of an edge) of the chamfer portion may vary. For example, by fixing the width (w) of the chamfer portion, a depth (A) of the chamfer portion at which the moiré phenomenon is eliminated may be derived, and the chamfer portion may be formed. According to an embodiment, the “y” length may be determined according to a refractive index of the material of the window 600, and the depth (A) of the chamfer portion may be determined according to the “y” length.

As illustrated in FIG. 10, it may be understood that as the length (e.g., “y” length) of the side surface at which total reflection causing the moiré phenomenon occurs is shortened, the moiré phenomenon decreases. For example, it may be confirmed that as a design depth (e.g., A-1, A-2, A-3, or A-4) of the chamfer portion becomes larger than a basic design depth (e.g., A) of the chamfer portion (e.g., as a C-cut amount of the chamfer portion becomes larger or as a length of the equilateral portion becomes larger), the moiré phenomenon decreases. For example, in FIG. 10, the depth (e.g., a vertical length or height) of the chamfer portion may be A<A-1<A-2<A-3<A-4, and it may be confirmed that the moiré phenomenon (e.g., see the element 1055) appears smallest at the depth A-4 of the chamfer portion. In particular, it is preferable that the depth (A) of the chamfer portion is at least 1.5 times the width (w) thereof. This ratio ensures that the vertical straight section responsible for the moiré phenomenon is sufficiently reduced to suppress total internal reflection without increasing the visually exposed width of the chamfer.

As illustrated in FIG. 10, in the present disclosure, in order to adjust (or suppress) the reflected light of the panel 700 causing the moiré phenomenon (e.g., to minimize a region where total reflection occurs), a shape of the chamfer portion may be designed by fixing the width (w) of the chamfer portion and designing the depth (A) of the chamfer portion to be deeper (longer), thereby improving the moiré phenomenon.

As illustrated in FIG. 10, the chamfer portion of the window 600 may have a designated width (w) in a horizontal direction and may be chamfered so that the chamfer portion extends by a designated length (e.g., a design depth or a vertical length) at a vertical straight section of the side surface of the window 600, thereby increasing the area of the chamfer portion.

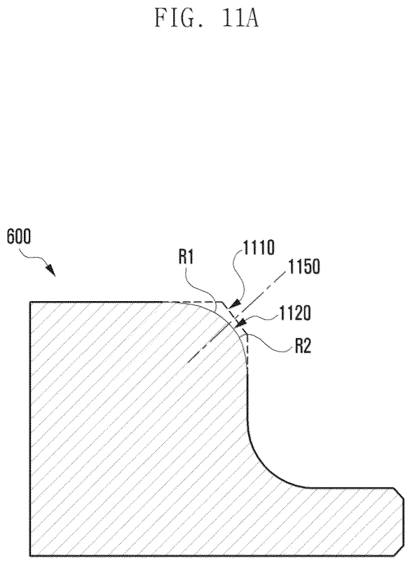

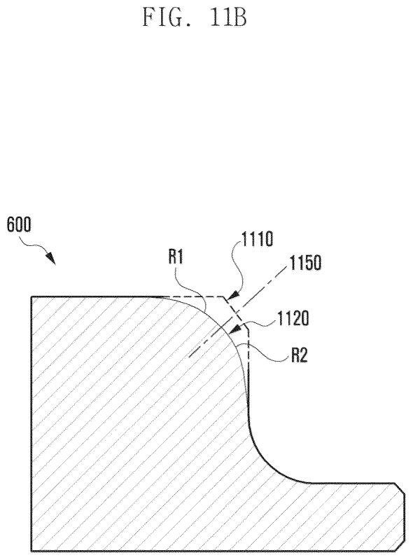

According to an embodiment, the example of FIG. 10 may be to design a shape of the chamfer portion by diagonally processing the chamfer portion of the window 600 by the depth (e.g., A-4) of the chamfer portion. The embodiments of the present disclosure are not limited thereto. According to an embodiment, in order to improve the moiré phenomenon, an edge portion of the window 600 may be processed to the length (e.g., A-4) of the chamfer portion so that the chamfer portion has a designated curvature (R), thereby designing a shape of the chamfer portion. According to an embodiment, in order to minimize a region where total reflection occurs, independently of or in parallel with the chamfering processing, a vertical straight section (e.g., the straight section 620 in FIG. 6 or FIG. 8) of the side surface of the window 600 may be changed to be diagonally inclined at a predetermined angle, thereby more effectively improving the moiré phenomenon. An example thereof is illustrated in FIGS. 11A to 15.

FIGS. 11A, 11B, 12, and 13 are views illustrating examples of window processing according to an embodiment of the present disclosure.

According to an embodiment, FIGS. 11A and 11B may illustrate examples of processing a shape of a chamfer portion 1110 of the window 600 of a basic design to have a designated curvature (R) (e.g., examples of forming the chamfer portion 1120 such that a side (e.g., an equilateral portion) of the chamfer portion 1110 has a curved shape based on at least one designated curvature (R)). For example, a curvature (R) may be varied according to a width (w) of a chamfer portion 1120 and a depth (A) of the chamfer portion 1120.

In an embodiment, the curvature (R) may vary depending on the width (w) of the chamfer portion 1120 and the depth (A) of the chamfer portion 1120 in such a way that a first curvature (R1) of a first portion (or first curved surface) of the window 600 (e.g., a curved surface corresponding (or close) to a front surface of the window 600 based on a reference line 1150) and a second curvature (R2) of a second portion (or second curved shape) of the window 600 (e.g., a curved surface corresponding (or close) to a side surface of the window 600 based on the reference line 1150) are equal (e.g., see FIG. 11A) or different (e.g., see FIG. 11B).

For example, when a length according to the width (w) of the chamfer portion 1120 and a length according to the depth (A) of the chamfer portion 1120 are the same (e.g., w=A), as illustrated in FIG. 11A, the chamfer portion 1120 may be formed as one curvature (R) in which the first curvature (R1) and the second curvature (R2) are the same. For example, according to the example of FIG. 11A, the first curvature (R1) and the second curvature (R2) may have the same curvature value (or radius of curvature). For example, when a length according to the width (w) of the chamfer portion 1120 and a length according to the depth (A) of the chamfer portion 1120 are different (e.g., w<A), as illustrated in FIG. 11B, the chamfer portion 1120 may be formed such that the first curvature (R1) and the second curvature (R2) are different, respectively. For example, according to the example of FIG. 11B, the first curvature (R1) and the second curvature (R2) may have different curvature values (or radii of curvature).

In an embodiment, as illustrated in FIG. 11B, the first curvature (R1) and the second curvature (R2) may be implemented differently. According to an embodiment, when the width (w) of the chamfer portion increases, the chamfer portion (e.g., a curved shape of the chamfer portion) may be more exposed to a user's line of sight toward the front surface of the window 600. According to an embodiment, as in the example of FIG. 10, by fixing the width (w) of the chamfer portion and variably applying only the second curvature (R2) according to the depth (A) of the chamfer portion, an extent to which the chamfer portion is exposed to a user's line of sight may be reduced.

To achieve a balance between visual aesthetics and moiré suppression, the first curvature (R1) close to the front surface is preferably 1.5 to 2.0 times larger than the second curvature (R2) close to the side surface. This asymmetry allows the window to maintain a smooth visual transition on the front while aggressively removing the total reflection area at the side.

According to an embodiment, as illustrated in FIG. 11A or FIG. 11B, the moiré phenomenon may be improved by processing a surface (e.g., an equilateral portion) of the chamfer portion to have a designated curvature, so that a size (e.g., a size of the equilateral portion of the chamfer portion) of the chamfer portion in the window 600 may be increased.

According to an embodiment, as illustrated in FIG. 11A or FIG. 11B, the window 600 may be formed such that the chamfer portion 1120 has a curved shape with a designated curvature (R) so as to reduce an amount of total reflection according to a refractive index of the window 600 at a side surface, and the side surface may extend from the curved surface of the chamfer portion 1120. According to an embodiment, a vertical straight section of the side surface may be formed to extend from the curved shape of the chamfer portion 1120 to be vertical or to have a designated slope.

As illustrated in FIGS. 11A and 11B, the chamfer portion of the window 600 may have a width (w) designated in a horizontal direction, and may be formed as a curved shape with a designated curvature (R) by extending by a designated length (e.g., a design depth or a vertical length) at a vertical straight section of the side surface of the window 600, thereby increasing the area of the chamfer portion.

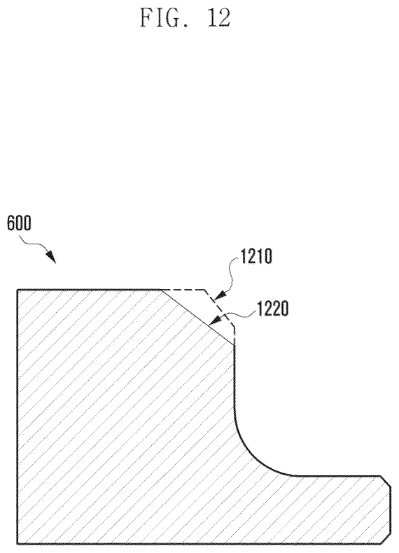

According to an embodiment, FIG. 12 may illustrate an example of processing a shape of a chamfer portion 1210 of a basic design in the window 600 into a chamfer portion 1220 in which a surface (e.g., an equilateral portion) of the chamfer portion has a designated length (or size) (e.g., an example of forming a chamfer portion 1220 such that a surface (e.g., equilateral portion) of the chamfer portion has a designated length (or size or area). For example, a designated length forming the surface of the chamfer portion may be varied according to the width (w) of the chamfer portion and the depth (A) of the chamfer portion. In an embodiment, the width (w) and the depth (A) of the chamfer portion may be formed to have the same or different lengths. In an embodiment, when a length according to the width (w) of the chamfer portion and a length according to the depth (A) of the chamfer portion are the same (e.g., w=A), a surface of the chamfer portion may have a slope (or angle) of about 45 degrees.

According to an embodiment, when the width (w) of the chamfer portion increases, the chamfer portion may be more exposed to a user's line of sight toward the front surface of the window 600. According to an embodiment, as in the example of FIG. 10, by fixing the width (w) of the chamfer portion and varying only the depth (A) of the chamfer portion, an extent to which the chamfer portion is exposed to a user's line of sight may be reduced.

According to an embodiment, as illustrated in FIG. 12, the window 600 may be formed such that an equilateral portion of the chamfer portion 1220 has a designated size so as to reduce an amount of total reflection according to a refractive index of the window 600 at a side surface, and the side surface may extend from the equilateral portion of the chamfer portion 1220. According to an embodiment, a vertical straight section of a side surface may be formed to extend from an equilateral portion of the chamfer portion 1220 to be vertical or to have a designated slope.

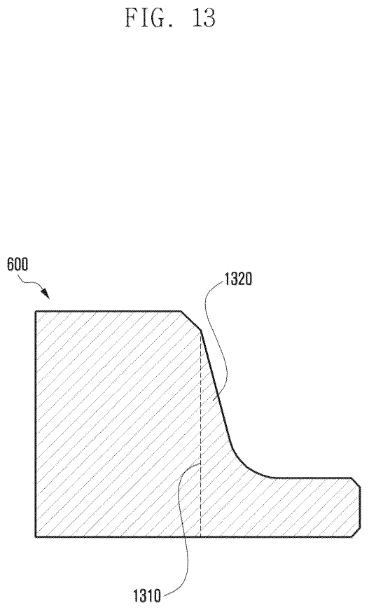

According to an embodiment, FIG. 13 may illustrate an example of inclinedly processing (or inclined processing) the side surface 1310 (e.g., the straight section in FIG. 2 or FIG. 8) of the window 600 perpendicular to the panel 700 so as to have a designated slope (e.g., a diagonal angle), while maintaining a shape of a chamfer portion of a basic design of the window 600 (e.g., forming the window 600 as a side surface 1320 having a slope rather than a vertical side surface). According to an embodiment, as illustrated in FIG. 13, a vertical straight section of a side surface 1310 of the window 600 perpendicular to the panel 700 may be diagonally processed to have a designated slope, extending from the chamfer portion 1120, 1220.

As illustrated in FIG. 11A, 11B, 12, or 13, according to an embodiment of the present disclosure, the moiré phenomenon may be reduced by changing a shape of the chamfer portion and/or a straight section (e.g., a side surface) perpendicular to the panel 700 so that the reflected light of the panel 700 deviates from a total reflection angle. According to various embodiments, as illustrated in the examples of FIG. 11A, 11B, 12, or 13, the moiré phenomenon may be improved in the window 600 of the electronic device 101 based on various design structures.

As illustrated in FIG. 11A, 11B, 12, or 13, according to an embodiment of the electronic device 101, the moiré phenomenon may be improved according to a structural change of the chamfer portion of the window 600 and/or a structural change of the side surface of the window 600. According to an embodiment, a structure for improving the moiré phenomenon may include, for example, a structure having a variable curvature (R) (e.g., a radius of curvature) (e.g., a first structure of FIG. 11A or FIG. 11B), a structure for changing a size (e.g., a C-cut amount) of an equilateral portion of a chamfer portion (e.g., a second structure of FIG. 12), and/or a structure for allowing a side surface (e.g., a straight section perpendicular to the panel 700 (e.g., the straight section 620 in FIG. 6 or FIG. 8)) to be inclined (e.g., a third structure of FIG. 13). According to an embodiment, the structure for improving the moiré phenomenon may follow the first structure, the second structure, or the third structure. According to an embodiment, the electronic device 101 may include a combination structure of the first structure and the third structure (e.g., a fourth structure) or a combination structure of the second structure and the third structure (e.g., a fifth structure) according to a design structure of the window 600.

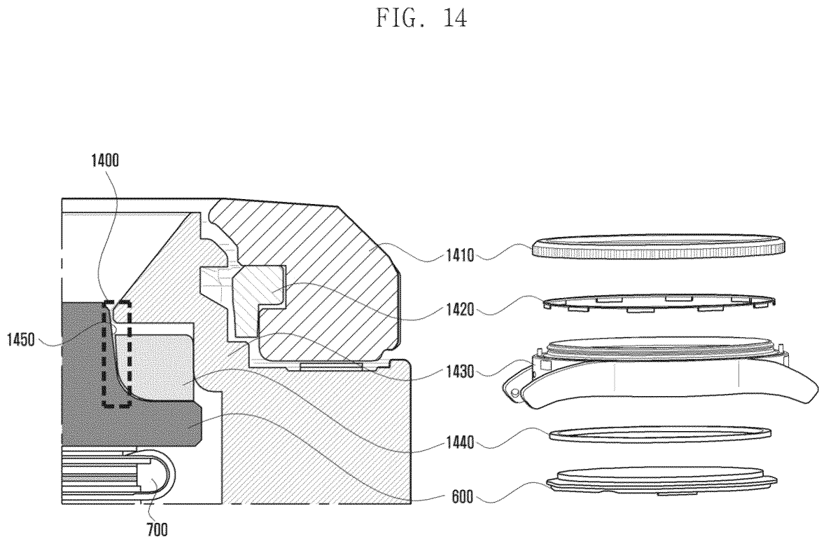

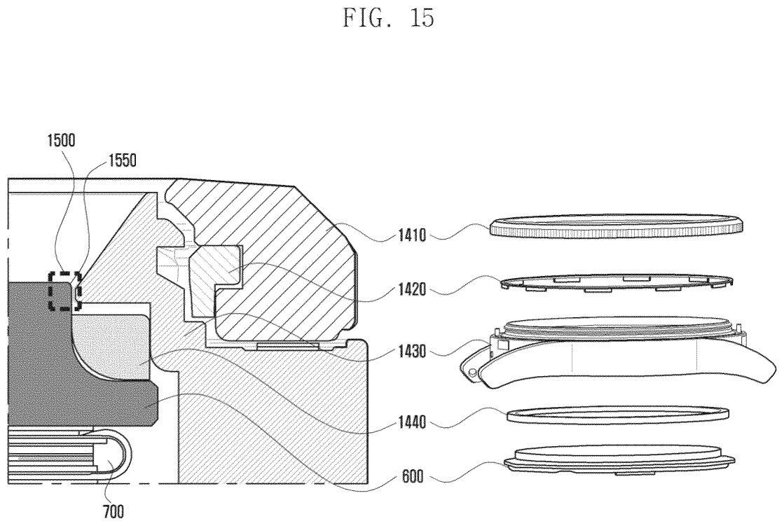

According to an embodiment, in order to improve the moiré phenomenon, the window 600 may be formed based on a side surface inclining scheme of the third structure as in the example of FIG. 13. An example thereof is illustrated in FIG. 14. According to an embodiment, in order to improve the moiré phenomenon, the window 600 may be formed based on a chamfering processing scheme of changing a size of an equilateral portion of a chamfer portion of the first structure or the third structure, as in the example of FIG. 11A, FIG. 11B, or FIG. 12. An example thereof is illustrated in FIG. 15.

FIG. 14 is a view illustrating an example in which a window is mounted in an electronic device according to an embodiment of the present disclosure.

FIG. 15 is a view illustrating an example in which a window is mounted in an electronic device according to an embodiment of the present disclosure.

According to an embodiment, the electronic device 101 of FIG. 14 or FIG. 15 may include at least some of the components described in the electronic device 101 of FIGS. 1 to 4, or may be implemented by further including other components.

According to an embodiment, with reference to FIG. 14 or FIG. 15, the electronic device 101 may include a wheel 1410 (e.g., the wheel key 202 of FIG. 4), a wheel deco 1420, a front 1430 (e.g., the side surface bezel structure 206 of FIG. 4), a waterproof ring 1440 (e.g., the sealing member 490 of FIG. 4), a window 600 (e.g., the front surface plate 201 of FIGS. 2 to 5), and a panel 700 (e.g., the display module 160 of FIG. 1 or the display 220 of FIG. 4).

According to an embodiment, as illustrated in FIG. 14 or FIG. 15, a front surface (e.g., the first surface 210A of FIGS. 2 to 5) of the electronic device 101 may be formed by a window 600 (e.g., the front surface plate 201 of FIGS. 2 to 5) in which at least one portion is substantially transparent. A rear surface (e.g., the second surface 210B of FIGS. 2 to 5) of the electronic device 101 may be formed by a rear surface plate (e.g., the rear surface plate 207 of FIGS. 2 to 4). According to an embodiment, a panel 700 (e.g., the display module 160 of FIG. 1 or the display 220 of FIG. 4) may be disposed below the window 600 of the electronic device 101. The panel 700 may be visually exposed through a substantial portion of the window 600. For example, a user may identify at least one content displayed on the panel 700 through the window 600.

According to an embodiment, the window 600 may be formed of various materials, such as a window of a first material (e.g., gorilla glass) or a window of a second material (e.g., sapphire glass). According to an embodiment, a moiré phenomenon may occur at an edge region of a front surface of the window 600. In an embodiment of the present disclosure, the moiré phenomenon occurring in the window 600 may be improved by adjusting the reflected light of the panel 700 through processing of a side surface of the window 600 and/or a chamfer portion of the window 600. For example, in the present disclosure, as in the example of FIG. 14 or FIG. 15, the reflected light causing the moiré phenomenon may be suppressed through a design change (or processing) of at least one portion of the window 600. According to an embodiment, the moiré phenomenon may be eliminated or improved through a design change of a total reflection angle region where the moiré phenomenon occurs at a side surface of the window 600.

According to an embodiment, with reference to FIG. 14, FIG. 14 may illustrate an example of forming the window 600 by changing a side surface1450 to be inclined (e.g., a diagonal form) (e.g., about 7-degree processing) (e.g., a third structure of FIG. 13) from a chamfer portion.

According to an embodiment, as illustrated in a dotted rectangular region 1400 in FIG. 14, a side surface 1450 of the window 600 (e.g., a straight section 620 perpendicular to the panel 700 (e.g., the straight section 620 in FIG. 6 or FIG. 8)) may be diagonally processed at a designated slope (or diagonal angle) (e.g., about n degrees) capable of eliminating reflected light, thereby eliminating the moiré phenomenon in the window 600. For example, the side surface 1450 of the window 600 may be inclined-processed to reduce an amount of total reflection, in consideration of a refractive index of a window material (e.g., sapphire glass) used in the electronic device 101. According to an embodiment, a designated slope (e.g., a diagonal angle) of the side surface 1450 may be calculated differently depending on the material of the window 600, as in the example of Table 1 below.

TABLE 1

| | | Total reflection | |
|---|---|---|---|
| Window | Refractive index | angle (deg) | Slope |
| Window of first material | Approx. 1.517 | Approx. 41.2 | Approx. n1 deg. |
| Window of second material | Approx. 1.76 | Approx. 34.6 | Approx. n2 deg. |

According to various embodiments, the window may have a refractive index n1 ranging from about 1.4 to about 1.9, preferably from about 1.5 to about 1.8, and more preferably from about 1.7 to about 1.8. The lower limit of about 1.4 is established to ensure the fundamental structural rigidity and protective function required for a wearable electronic device, as materials with an excessively low refractive index may fail to sufficiently protect the panel from external impacts or provide the necessary seating for the window within the case. The upper limit of about 1.9 is determined based on the optical limitation where an increase in the refractive index n1 causes the critical angle for total reflection to decrease according to Equation 1, and a refractive index exceeding this limit may result in a total reflection region that is technically difficult to suppress even with the structural modifications of the side surface or the chamfer portion disclosed herein. Within the preferred range of about 1.5 to about 1.8, the window can effectively incorporate a first material (e.g., gorilla glass) with a refractive index of approximately 1.517 or a second material (e.g., sapphire glass) with a refractive index of approximately 1.76. Within this range, the moiré phenomenon can be precisely controlled by optimizing the depth (A) of the chamfer portion or the designated slope of the straight section (e.g., side wall section) to redirect the reflected light away from the user's line of sight. In particular, the more preferred range of about 1.7 to about 1.8 is specifically optimized for high-refractive-index materials such as sapphire glass, where a relatively low total reflection angle of approximately 34.6 degrees typically intensifies screen distortion at the edge region. Such intensified distortion is effectively mitigated by diagonally processing the side wall section to have a specific slope (e.g., approximately n2 degrees) based on the specific refractive index to remove the total reflection section.

The designated slope (diagonal angle) of the straight section is preferably in a range of 5 degrees to 15 degrees, more preferably 5 degrees to 10 degrees, even more preferably 6 degrees to 9 degrees, and most preferably 7 degrees to 8 degrees relative to the direction perpendicular to the panel. In particular, when the slope is approximately 7 degrees, the total reflection of the reflected light is optimally suppressed in a window made of sapphire glass, thereby maximizing the elimination of the moiré phenomenon while maintaining the structural stability of the window edge.

With reference to Table 1, according to an embodiment, when assuming that a refractive index of a window of a first material is about 1.517 and a total reflection angle is about 41.2, a side surface 1450 of the window 600 may be diagonally processed by about n1 degrees to improve the moiré phenomenon. According to an embodiment, when assuming that a refractive index of a window of a second material is about 1.76 and a total reflection angle is about 34.6, a side surface 1450 of the window 600 may be diagonally processed by about n2 degrees to improve the moiré phenomenon. As in the example of Table 1, in the case of diagonal processing of the side surface 1450 of the window 600, the higher the refractive index of a material, the larger the slope. For example, in the example of Table 1, the slope may have a value larger than about n2 degrees or about n1 degrees.

According to an embodiment, with reference to FIG. 15, FIG. 15 may illustrate an example of forming the window 600 by changing (e.g., increasing a C-CUT amount) a size (e.g., a C-CUT amount) of an equilateral portion of a chamfer portion by a first structure (e.g., a variable R scheme) of FIG. 11A or FIG. 11B or a second structure (e.g., a composite C scheme) of FIG. 12.

According to an embodiment, as illustrated in a dotted rectangular region 1500 of FIG. 15, the moiré phenomenon in the window 600 may be eliminated by processing a chamfer portion 1550 of the window 600 into a curved shape having a designated curvature R with a designated size capable of eliminating reflected light, or into a shape having a designated C-CUT size. For example, at the chamfer portion 1550, a size (e.g., a size of an equilateral portion of the chamfer portion 1550) of the chamfer portion 1550 may be processed so as to reduce an amount of total reflection according to a refractive index of the window 600, through an asymmetric curved shape such as front surface R of about 0.35+side surface R of about 0.2. According to an embodiment, the front surface and side surface of the chamfer portion 1550may also be processed into a symmetric curved shape, such as front surface R of about 0.2+side surface R of about 0.2. For example, at the chamfer portion 1550, a size of the chamfer portion 1550 may be processed so as to reduce an amount of total reflection according to a refractive index of the window 600, through asymmetric cutting of the front surface and/or side surface of the chamfer portion 1550, such as front surface C of about 0.35+side surface C of about 0.2. According to an embodiment, the chamfer portion 1550 may be cut in such a manner that the front surface and the side surface are cut symmetrically, such as front surface C of about 0.2+side surface C of about 0.2. According to an embodiment, the chamfer portion 1550 (e.g., a C-CUT section) may be processed in size so as to reduce an amount of total reflection, in consideration of a refractive index according to the material (e.g., sapphire glass) of the window 600 used in the electronic device 101.

According to various embodiments of the present disclosure, there is an effect of improving display quality by eliminating the moiré phenomenon. According to an embodiment of the present disclosure, regardless of a material (or material type) of the window, the moiré phenomenon may be eliminated or improved by changing a window structure according to the window material. According to an embodiment, regardless of a design of the electronic device, the moiré phenomenon may be eliminated by processing a shape of a window glass. According to an embodiment, the moiré phenomenon may be eliminated by processing the glass with an inclination on a side surface in such a way as to have an optimum slope according to a window material, or by processing a chamfer portion up to a total reflection angle region where the moiré phenomenon occurs, depending on the window material. According to an embodiment, a chamfer portion may be processed so that a size (or a C-CUT amount) of the chamfer portion increases, through symmetric or asymmetric cutting of the front surface and the side surface of the chamfer portion, thereby eliminating the moiré phenomenon.

According to an embodiment of the present disclosure, the electronic device 101 (e.g., a wearable electronic device) may include a panel 700 and a window 600 formed on the panel 700. According to an embodiment, the window 600 may include a front surface, a side surface, and a chamfer portion (e.g., the chamfer portion comprises or is configured to beveled surface) connecting the front surface and the side surface. According to an embodiment, a vertical straight section (e.g., straight section, or side wall section) of the side surface of the window 600, which is perpendicular to the panel 700, may be diagonally processed to have a designated slope, extending from the chamfer portion.

According to an embodiment, at the side surface of the window 600, different refractive indexes may be formed depending on the material forming the window 600.

According to an embodiment, the designated slope may be determined based on a total reflection angle according to a refractive index of the window 600.

According to an embodiment, the window 600 may be formed of a first material or a second material.

According to an embodiment, the window 600 may be processed so that the side surface has a designated slope according to the first material or the second material, and/or the chamfer portion has a designated size or curvature.

According to an embodiment, the window 600 may include a window of a first material or a window of a second material.

According to an embodiment, a refractive index of the window of the first material and a refractive index of the window of the second material may be different from each other.

According to an embodiment, the window 600 and the panel 700 may be disposed substantially in parallel.

According to an embodiment, a vertical straight section of the side surface may be formed to have a length calculated based on the total reflection angle.

According to an embodiment, the chamfer portion may be chamfered to have a designated width in a horizontal direction of the chamfer portion, and to extend by the length of the vertical straight section of the side surface, thereby increasing the area of the chamfer portion.

According to an embodiment, the window 600 may be formed into a curved shape in which the chamfer portion has a designated curvature, so as to reduce an amount of total reflection according to a refractive index of the window 600 at the side surface.

According to an embodiment, the chamfer portion may be formed into a curved shape having a designated curvature, while having a designated width in a horizontal direction of the chamfer portion, and extending by the length of the vertical straight section of the side surface, thereby increasing the area of the chamfer portion.

According to an embodiment, the window 600 may be formed into a shape in which an equilateral portion of the chamfer portion has a designated size, so as to reduce an amount of total reflection according to a refractive index of the window 600 at the side surface.

According to an embodiment, the chamfer portion may be formed so that the designated size of the equilateral portion of the chamfer portion increases by extending by the length of the vertical straight section calculated based on the total reflection angle.

According to an embodiment, the window 600 may be formed into a shape in which the side surface has a designated slope, so as to reduce an amount of total reflection according to a refractive index of the window 600 at the side surface.

According to an embodiment, the window 600 may be formed into a curved shape in which the chamfer portion has a designated curvature, so as to reduce an amount of total reflection according to a refractive index of the window 600 at the side surface, and the side surface may be formed to extend from the curved surface of the chamfer portion to have a designated slope.

According to an embodiment, the window 600 may be formed so that the chamfer portion is formed into a curved shape having a designated curvature, and a vertical straight section of the side surface extends from the curved surface of the chamfer portion to have a designated slope.

According to an embodiment, the window 600 may be formed into a shape in which an equilateral portion of the chamfer portion has a designated size, so as to reduce an amount of total reflection according to a refractive index of the window 600 at the side surface, and the side surface may extend from the equilateral portion of the chamfer portion to have a designated slope.

According to an embodiment, the window 600 may be formed so that an equilateral portion of the chamfer portion has a designated size according to a length calculated based on a total reflection angle, and a vertical straight section of the side surface extends from the equilateral portion of the chamfer portion to have a designated slope.

According to an embodiment, the window 600 may be formed into a structure having a total reflection angle region that minimizes an amount of total reflection in consideration of a refractive index according to a material of the window 600.

According to an embodiment, the window 600 may be formed into a structure in which a total reflection section is removed from the vertical straight section of the side surface.

According to an embodiment, the window 600 may be processed by using a chamfer processing value set for diagonal processing of the side surface and/or chamfering processing of the chamfer portion.

According to an embodiment, the chamfer processing value may include a slope of the side surface.

According to an embodiment, the chamfer processing value may include a curvature of symmetry/asymmetry for a curved surface, or a length for an equilateral portion, based on a shape of the chamfer portion formed between the front surface and the side surface.

Hereinafter, a method of processing a window of the electronic device 101 of various embodiments will be described. Operations (e.g., window processing operations) performed on the electronic device 101 according to various embodiments may be executed by a processor 120 including various processing circuitry and/or executable program elements. According to an embodiment, the operations performed in the electronic device 101 may be stored as instructions in a memory 130, and may be performed individually and/or collectively by the processor 120.

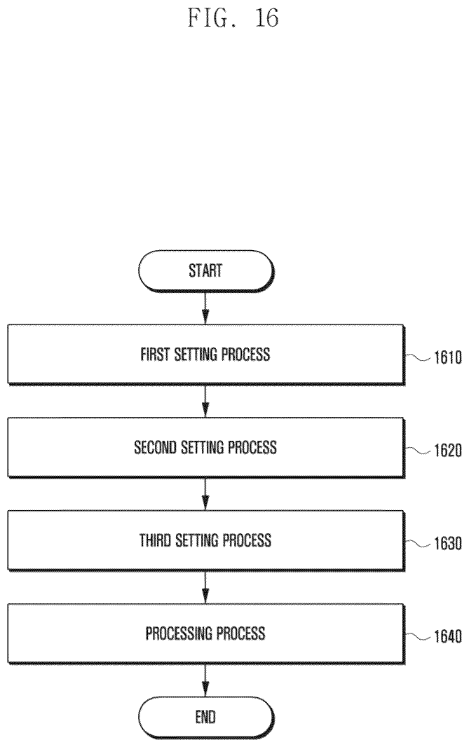

FIG. 16 is a flowchart illustrating an example of a method of processing a window of an electronic device according to an embodiment of the present disclosure.

A method of processing a window 600 for an electronic device 101 according to an embodiment of the present disclosure may proceed, for example, in the sequence of the flowchart illustrated in FIG. 16. The flowchart illustrated in FIG. 16 is an example according to an embodiment of a method of processing the window 600, and the sequence of at least some operations may be modified, performed in parallel, or performed as independent operations, or at least some other operations may be performed complementarily to at least some operations.

With reference to FIG. 16, a window processing method according to an embodiment may proceed in the order of a first setting process 1610, a second setting process 1620, a third setting process 1630, and a window 600 processing process 1640.

In an embodiment, the first setting process 1610 may include a process of setting a refractive index for each material of the window 600. According to an embodiment, a refractive index corresponding to a material (e.g., a first material or a second material) of the window 600 mounted in the electronic device 101 may be set. For example, the window 600 may be formed of various materials, and a refractive index for each material of the window 600 may be different. In an embodiment, information about the refractive index according to the material of the window 600 may be preset in a design system for the window 600.

In an embodiment, the second setting process 1620 may include a process of setting a designated processing scheme. According to an embodiment, the second setting process 1620 may be a process of setting a processing scheme for forming a structure of the window 600. For example, the second setting process 1620 may be a process of determining a processing scheme corresponding to a structural change of a side surface of the window 600 and/or a structural change of a chamfer portion of the window 600. According to an embodiment, the processing scheme for forming a structure of the window 600 may include a processing scheme for processing the side surface and/or the chamfer portion of the window 600 so as to reduce an amount of total reflection according to a refractive index of the window 600 at the side surface.

According to an embodiment, the processing scheme for forming a structure of the window 600 may include, for example, a first processing scheme for processing the chamfer portion of the window 600 into a structure having a variable R (e.g., a radius of curvature) (e.g., a first structure of FIG. 11A or FIG. 11B), a second processing scheme for processing the chamfer portion of the window 600 into a structure with an increased C-CUT amount (e.g., a second structure of FIG. 12), and/or a third processing scheme for processing the side surface of the window 600 into an inclined structure having a designated slope (or diagonal angle) (e.g., a third structure of FIG. 13).

According to an embodiment, the processing scheme for forming a structure of the window 600 may follow a design structure such as the first structure, the second structure, or the third structure. According to an embodiment, the processing scheme for forming a structure of the window 600, depending on a design structure forming the window 600, may include a fourth processing scheme for processing into a combination structure of the first structure and the third structure (e.g., a fourth structure) or a fifth processing scheme for processing into a combination structure of the second structure and the third structure (e.g., a fifth structure). According to an embodiment, a designated processing scheme of the window 600 may be set as a suitable processing scheme for forming a design of the electronic device 101, in consideration of a design of the electronic device 101. According to an embodiment, a designated processing scheme of the window 600 may be set as a processing scheme of a structure capable of minimizing an amount of total reflection in consideration of a refractive index according to a material of the window 600.

In an embodiment, the third setting process 1630 may include a process of setting a chamfer processing value corresponding to a refractive index in the designated processing scheme. According to an embodiment, the third setting process 1630 may be a process of setting a chamfer processing value to be used for processing a side surface and/or chamfer portion of the window 600, in the designated processing scheme determined through the second setting process 1620. For example, the chamfer processing value may include a slope (e.g., a diagonal angle) of the side surface, and/or a symmetric/asymmetric radius of curvature (e.g., R), or a length (e.g., a length w of a front surface and/or a length y of a side surface), of a front surface and a rear surface of a chamfer portion.

In an embodiment, the processing process 1640 may include a process of processing a side surface and/or chamfer portion of the window 600, based on the designated processing scheme and the chamfer processing value. For example, the processing process 1640 may be a process performed by diagonally processing the side surface of the window 600, and/or by using chamfering (e.g., C-CUT) processing of a chamfer portion of the window 600.

According to an embodiment of the present disclosure, by processing a side surface and/or a chamfer portion of a window 600 with a designated processing scheme, an amount of total reflection in the window 600 may be minimized to improve a moiré phenomenon.

A method of processing the window 600 of the electronic device 101 (e.g., a wearable electronic device) according to an embodiment of the present disclosure may include an operation (e.g., a first setting process 1610) of setting a refractive index for each material of the window 600. According to an embodiment, the method may include an operation (e.g., a second setting process 1620) of setting a designated processing scheme. According to an embodiment, the method may include an operation (e.g., a third setting process 1630) of setting a chamfer processing value corresponding to a refractive index in the designated processing scheme. According to an embodiment, the method may include an operation (e.g., a processing process 1640) of processing the side surface and/or the chamfer portion of the window 600, based on the designated processing scheme and the chamfer processing value.

According to an embodiment, the window 600 may be formed of a first material or a second material.

According to an embodiment, the window processing method may perform the first setting process by using a refractive index for the window 600 corresponding to the first material or the second material.

According to an embodiment, the window 600 may be formed of the first material or the second material, and different refractive indexes may be formed at the side surface of the window 600 depending on the material forming the window 600, and the first setting process may be performed using a total reflection angle according to the refractive index of the window 600.

According to an embodiment, the first setting process may include calculating a length of a vertical straight section of the side surface based on the total reflection angle.

According to an embodiment, a refractive index of the window of the first material and a refractive index of the window of the second material may be different from each other.

According to an embodiment, the second setting process may be performed by using a processing scheme corresponding to a structural change of the side surface of the window 600 and/or a structural change of the chamfer portion of the window 600.

According to an embodiment, the designated processing scheme may include a processing scheme for processing the side surface and/or the chamfer portion of the window 600 so as to reduce an amount of total reflection according to a refractive index of the window 600 at the side surface.

According to an embodiment, the designated processing scheme may include a diagonal processing scheme of processing a vertical straight section of the side surface of the window 600 to have a designated slope by extending from the chamfer portion, and/or a chamfering processing scheme of processing the chamfer portion to increase the area of the chamfer portion by having a designated width in a horizontal direction of the chamfer portion and extending by the length of the vertical straight section of the side surface.

According to an embodiment, the designated processing scheme may include a first processing scheme of processing the chamfer portion of the window 600 into a first structure having a designated curvature according to the length.

According to an embodiment, the designated processing scheme may include a second processing scheme of processing the chamfer portion of the window 600 into a second structure in which a size of an equilateral portion of the chamfer portion has a designated size according to the length.

According to an embodiment, the designated processing scheme may include a third processing scheme of processing the side surface of the window 600 into a third structure having a designated slope by extending from the chamfer portion.

According to an embodiment, the designated processing scheme may include a fourth processing scheme of processing into a fourth structure by a combination of the first structure and the third structure.

According to an embodiment, the designated processing scheme may include a fifth processing scheme of processing into a fifth structure by a combination of the second structure and the third structure.

According to an embodiment, the second setting process may be performed by using a processing scheme of a structure capable of minimizing an amount of total reflection in consideration of a refractive index according to a material of the window 600.

According to an embodiment, the third setting process may be performed by using a chamfer processing value to be used for processing a side surface and/or a chamfer portion of the window 600.

According to an embodiment, the chamfer processing value may include a slope of the side surface.

According to an embodiment, the chamfer processing value may include a curvature of symmetry/asymmetry for a curved surface, or a length for an equilateral portion, based on a shape of the chamfer portion formed between the front surface and the side surface.

According to an embodiment, the processing process may be performed by using diagonal processing of the side surface of the window 600, and/or chamfering processing of the chamfer portion of the window 600.

In a non-transitory computer-readable medium storing instructions to be executed by a processor 120 of the electronic device 101 according to an embodiment of the present disclosure, the instructions, when executed by the processor 120, may cause the electronic device 101 to perform an operation (e.g., a first setting process) of setting a refractive index for each material of the window 600, an operation (e.g., a second setting process) of setting a designated processing scheme, an operation (e.g., a third setting process) of setting a chamfer processing value corresponding to a refractive index in the designated processing scheme, and an operation (e.g., a processing process) of processing a side surface and/or chamfer portion of the window 600 based on the designated processing scheme and the chamfer processing value.

It will be understood that the above-described embodiments and their technical features may be combined with each other in every combination, as long as there is no conflict between two embodiments or features. For example, every combination of two or more of the above-described embodiments may be conceived and included within the scope of the present disclosure. One or more features from any embodiment may be integrated into any other embodiment and may provide corresponding advantages.

The electronic device according to various embodiments disclosed in the present document may be a device in various forms. The electronic device may include, for example, a portable communication device (e.g., a smartphone), a computer device, a portable multimedia device, a portable medical device, a camera, a wearable device, or a home appliance. The electronic device according to the embodiment of the present document is not limited to the above-mentioned devices.

Various embodiments of this document and the terms used in the embodiments are not intended to limit the technical features disclosed in this document to the particular embodiments and should be understood as including various alterations, equivalents, or alternatives of the corresponding embodiments. In connection with the description of the drawings, the same or similar reference numerals may be used for the similar or related components. The singular form of a noun corresponding to an item may include one or a plurality of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of, the items enumerated together in a corresponding one of the phrases. As used herein, such terms as “1st” and “2nd,” or “first” and “second” may be used to simply distinguish a corresponding component from another, and does not limit the components in other aspect (e.g., importance or order). If a component (e.g., a first component) is referred to, with or without the term “operatively” or “communicatively,” as “coupled with,” “coupled to,” “connected with,” or “connected to” another component (e.g., a second component), it means that the component may be coupled with the other component directly (e.g., wired), wirelessly, or via a third component.

The term “module” used in various embodiments of the present document may include a unit implemented in hardware, software, or firmware, and may interchangeably be used with other terms, for example, “logic,” “logic block,” “part,” or “circuitry”. The module may be a single integral component, or a minimum unit or part thereof, adapted to perform one or more functions. For example, according to one embodiment, the module may be implemented in a form of an application-specific integrated circuit (ASIC).

Various embodiments as set forth herein may be implemented as software (e.g., the program 140) including one or more instructions that are stored in a storage medium (e.g., an internal memory 136 or an external memory 138) that is readable by a machine (e.g., the electronic device 101). For example, the processor (e.g., processor 120) of the machine (e.g., electronic device 101) may invoke and execute at least one of one or more instructions stored from the storage medium. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Here, “non-transitory” only means that the storage medium is a tangible device and does not include signals (e.g., electromagnetic waves), and this term does not distinguish between the case where the data is stored on the storage medium permanently and the case where the data is stored temporarily.

According to one embodiment, the methods according to various embodiments disclosed in this document may be included in and provided as a computer program product. The computer program product may be traded as a product between a seller and a buyer. The computer program product may be distributed in the form of a machine-readable storage medium (e.g., compact disc read only memory (CD-ROM)), or it may be distributed online (e.g., downloaded or uploaded) through an application store (e.g., Play Store™) or directly between two user devices (e.g., smartphones). In case of the distribution online, at least part of the computer program product may be at least temporarily stored or temporarily generated in the machine-readable storage medium, such as memory of the manufacturer's server, a server of the application store, or a relay server.

According to various embodiments, each component (e.g., module or program), among the above-mentioned components, may include a single object or a plurality of objects, and some of the plurality of objects may be disposed separately in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

The various embodiments disclosed in the present specification and drawings are provided as examples merely for easily explaining the technical contents and helping understand the present disclosure, but not intended to limit the scope of the technology disclosed in the present disclosure. Therefore, the scope of the present disclosure should be interpreted that all changes or modified forms derived based on the technical teachings of the present disclosure fall within the scope of the present disclosure in addition to the embodiments disclosed herein.

What is claimed is:

1. An electronic device comprising:
a panel; and
a window on the panel,
wherein the window comprises a front surface, a side surface, and a chamfer portion between the front surface and the side surface,
wherein the side surface comprises a straight section extending from the chamfer portion toward the panel, and
wherein the straight section has a designated slope relative to a direction perpendicular to the panel.

2. The electronic device of claim 1, wherein the window comprises different refractive indexes at the side surface depending on a material of the window,
wherein the designated slope corresponds to a total reflection angle according to a refractive index of the window, and
wherein the straight section of the side surface has a length corresponding to the total reflection angle.

3. The electronic device of claim 2, wherein the chamfer portion has a designated width in a horizontal direction of the chamfer portion, and
wherein the chamfer portion extends to the length of the straight section of the side surface.

4. The electronic device of claim 2, wherein the chamfer portion has a curved shape having a designated curvature and a designated width in a horizontal direction of the chamfer portion, and
wherein the chamfer portion extends to the length of the straight section of the side surface.

5. The electronic device of claim 2, wherein the chamfer portion comprises an equilateral portion having a designated size, and the chamfer portion extends to the length of the straight section.

6. The electronic device of claim 1, wherein the chamfer portion has a designated curvature, and
wherein the straight section of the side surface extends from a curved surface of the chamfer portion.

7. The electronic device of claim 1, wherein the chamfer portion comprises an equilateral portion having a designated size corresponding to a length calculated based on a total reflection angle, and
wherein the straight section of the side surface extends from the equilateral portion of the chamfer portion to have the designated slope.

8. The electronic device of claim 1, further comprising:
a structure housing the window.

9. A method of processing a window of an electronic device, the method comprising:
performing a first setting process of setting a refractive index for each material of the window;
performing a second setting process of setting a designated processing scheme;
performing a third setting process of setting a chamfer processing value corresponding to a refractive index in the designated processing scheme; and
performing a processing process for processing a side surface and/or a chamfer portion of the window based on the designated processing scheme and the chamfer processing value.

10. The method of claim 9, wherein the window is formed of a first material or a second material,
wherein the side surface of the window is formed to have different refractive indexes based on the first material or the second material, and
wherein the first setting process is performed by using a total reflection angle according to the refractive index set for each material of the window.

11. The method of claim 10, wherein the first setting process comprises:
calculating a length of a straight section of the side surface based on the total reflection angle,
wherein the second setting process comprises:
performing by using a processing scheme corresponding to a structure change of the side surface of the window and/or a structure change of the chamfer portion of the window,
wherein the third setting process comprises:
performing by using the chamfer processing value to process the side surface and/or the chamfer portion of the window,
wherein the chamfer processing value comprises:
at least one of a slope of the side surface or a curvature of symmetry or asymmetry for a curved surface or a length of an equilateral portion, based on a shape of the chamfer portion formed between a front surface and the side surface, and
wherein the processing process comprises:
performing by using at least one of diagonal processing of the side surface of the window or chamfering processing of the chamfer portion of the window.

12. The method of claim 11, wherein the designated processing scheme comprises at least one of:
a scheme of diagonally processing a straight section of the side surface of the window to have a designated slope, extending from the chamfer portion; or
a chamfering processing scheme of increasing the area of the chamfer portion by having a designated width in a horizontal direction of the chamfer portion and extending by the length of the straight section of the side surface.

13. A non-transitory computer-readable recording medium storing one or more instructions, wherein the one or more instructions, when executed by at least one processor of electronic device, cause the electronic device to:
set a refractive index for each material of a window;
set a designated processing scheme;
set a chamfer processing value corresponding to a refractive index in the designated processing scheme; and
process at least one of a side surface or a chamfer portion of the window based on the designated processing scheme and the chamfer processing value.

14. The electronic device of claim 1, wherein the window comprises a first material and a second material, and
wherein a refractive index of the first material is different than a refractive index of the second material.

15. The electronic device of claim 1, wherein the refractive index of the first material and the refractive index of the second material range from 1.4 to 1.9.

16. The electronic device of claim 1, wherein the chamfer portion comprises a first portion and second portion, wherein the first portion is close to the front surface of the window, and the second portion is close to the side surface of the window.

17. The electronic device of claim 16, wherein a depth of the chamfer portion is identical to a width of the chamfer portion, wherein a curvature of the first portion is identical to a curvature of the second portion.

18. The electronic device of claim 16, wherein the curvature of the first portion is higher than the curvature of the second portion.

19. The electronic device of claim 18, wherein the curvature of the first portion is 1.5 to 2.0 times larger than the curvature of the second portion.

20. The electronic device of claim 16, wherein the designated slope of the chamfer portion is about 7 degrees.
